(19) United States
(12) Patent Application Publication
(10) Pub. No.: US 2008/0048698 A1
(43) Pub. Date: Feb. 28, 2008

(54) Probe Card

(76) Inventors: Takashi Amemiya, Yamanashi (JP); Hisatomi Hosaka, Yamanashi (JP); Toshihiro Yonezawa, Yamanashi (JP); Syuichi Tsukada, Yamanashi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/630,004

(22) PCT Filed: Jun. 29, 2005
(86) PCT No.: PCT/JP05/11937

§ 371 Date: Sep. 10, 2007

(30) Foreign Application Priority Data
Jun. 29, 2004 (JP) 2004-191401

(51) Int. Cl. G01R 1/073; H01L 21/66

(52) U.S. Cl. 324/758

(57) ABSTRACT

It is an object of the present invention to conduct highly reliable inspection by adjusting a contactor of a probe card and an inspection object in a prober to a parallel state even if the contactor and the inspection object become not parallel to each other. The present invention is a probe card mounted in a prober via a holder, the probe card including: a contactor; a circuit board electrically connected to the contactor; a reinforcing member reinforcing the circuit board; and a parallelism adjustment mechanism adjusting a degree of parallelism between the contactor and an inspection object disposed in the prober.

### TECHNICAL FIELD

The present invention relates to a probe card which is used in inspecting electrical characteristics of an inspection object such as a wafer, more particularly, to a probe card including a parallelism adjustment mechanism which can adjust a probe card and an inspection object to a parallel state, thereby making a contact pressure constantly uniform.

### BACKGROUND ART

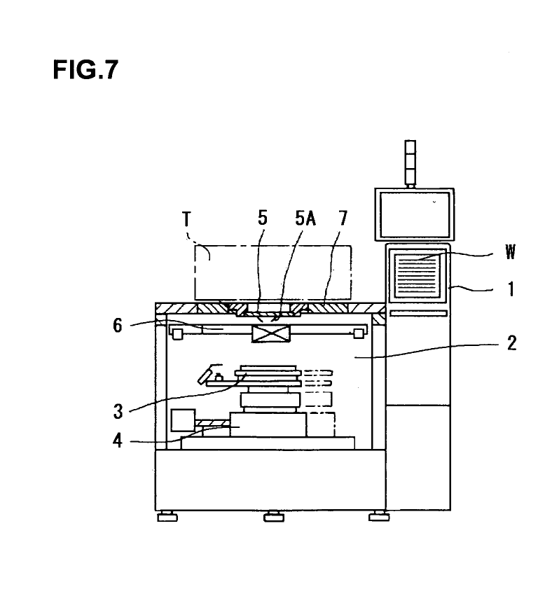

A probe card is mounted in a prober shown in, for example, FIG. 7 when in use. As shown in FIG. 7, the prober includes a loader chamber 1 for transferring a wafer W and a prober chamber 2 in which electrical characteristics of the wafer W delivered from the loader chamber 1 are inspected, and after the wafer W is pre-aligned in a transfer process of the wafer W in the loader chamber 1, the electrical characteristics of the wafer W are inspected in the prober chamber 2.

As shown in FIG. 7, the prober chamber 2 includes: a mounting table (main chuck) 3 on which the wafer W having been pre-aligned is placed and whose temperature is adjustable; an XY table 4 for moving the main chuck 3 in an X direction and a Y direction; a probe card 5 disposed above the main chuck 3 moved by the XY table 4; and a positioning mechanism (alignment mechanism) 6 accurately aligning a plurality of probes 5A of the probe card 5 with a plurality of electrode pads of the wafer W on the main chuck 3.

Further, as shown in FIG. 7, a test head T of a tester is rotatably disposed on a head plate 7 of the probe chamber 2, and the test head T and the probe card 5 are electrically connected to each other via a performance board (not shown). The temperature of the wafer W on the main chuck 3 is set to a value within a temperature range from, for example, −20° C. to +150° C., the tester transmits inspection signals to the probes 5A via the test head T and the performance board, and the probes 5A apply the inspection signals to the electrode pads of the wafer W, thereby inspecting the electrical characteristics of a plurality of semiconductor elements (devices) formed on the wafer W. At the time of high-temperature inspection, the wafer is heated to a predetermined temperature (100° C. or higher) via a temperature adjustment mechanism (heating mechanism) installed in the main chuck 3 and then is inspected.

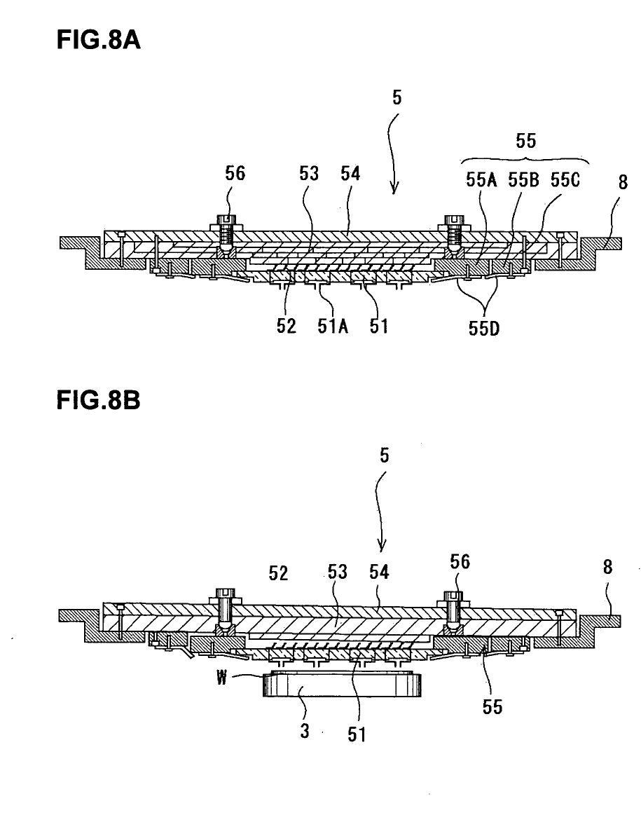

Next, the probe card 5 will be described with reference to FIGS. 8(a) and 8(b). As shown in, for example, FIG. 8(a), the probe card 5 includes: a contactor 51 having a plurality of probes 51A; a plurality of contacts 52 as elastic intermediate members connected to an upper surface of the contactor 51; a printed wiring board 53 in electrical contact with these contacts 52; a reinforcing member 54 made of metal such as stainless steel for reinforcing the printed wiring board 53; and a fastening means 55 for fastening the contactor 51 and the printed wiring board 53 integrally with the reinforcing member 54. A card holder 8 is attached to the probe card 5 as shown in, for example, FIG. 8, and the probe card 5 is mounted in the prober via the card holder 8.

The fastening means 55 has: a first fixing member 55A fixing the contactor 51 to the printed wiring board 54; a second fixing member 55B fixing the first fixing member 55A to the printed wiring board 53; and a plurality of screw members 55C fixedly fastening the second fixing member 55B to the printed wiring board 53. The contactor 51 is pressed to the printed wiring board 53 side by a plurality of leaf springs 55D attached to the first fixing member 55A, and the first fixing member 55A is pressed to the printed wiring board 53 side by a plurality of leaf springs 55D attached to the second fixing member 55B.

Further, as shown in FIG. 8(a), the probe card 5 has a pressure adjustment mechanism 56 which adjusts a contact pressure between the plural contacts 52 attached to the contactor 51 and the printed wiring board 53 to enable the adjustment of the contact pressure of each of the contacts 52 to a proper value. Therefore, even if a thermal influence and the like at the time of the inspection causes some irregularities and the like in the printed wiring board 53 to lower flatness of the printed wiring board 53 and thus the contact between the contacts 52 and the printed wiring board 53 becomes unstable, the pressure adjustment mechanism 56 is capable of eliminating the contact failure by adjusting the contact pressure. The probe card 5 including the pressure adjustment mechanism of this type is proposed in, for example, a patent document 1. The patent document 1 describes a probe used in inspecting electrical characteristics of an inspection object such as a wafer, more particularly, a probe whose stylus pressure at the time of the inspection can be reduced.

[Patent document 1] Japanese Translation of PCT Publication No. 2001-524258

### DISCLOSURE OF THE INVENTION

[Problems to Be Solved by the Invention]

However, in the conventional probe card 5, though the contact failure between the contactor 51 and the printed wiring board 53 can be solved by the pressure adjustment mechanism 56, it is difficult to make the probe card 5 mounted in the prober and the wafer W on the main chuck 3 in the prober parallel to each other by using another mechanism in the prober in a case where the prober and the wafer W become not parallel to each other, and therefore, the contactor 51 and the wafer W can be made parallel to each other by utilizing the pressure adjustment mechanism 56. In this case, however, the plural contacts 52 attached to the contactor 51 and the printed wiring board 53 become not parallel to each other and contact failure occurs between the contacts 52 and the printed wiring board 53. There has been a problem that in an extreme case, some of the contacts 52 cannot come into contact with the printed wiring board 53 as shown in FIG. 8(b), so that the inspection of the wafer W cannot be conducted. Such a problem also occurs in a probe card which does not include the contacts 52 or the pressure adjustment mechanism 56 and in which the contactor and the printed wiring board are directly connected.

The present invention was made to solve the above problem and an object thereof is to provide a probe card which includes a parallelism adjustment mechanism and is capable of highly reliable inspection by adjusting a contactor of the probe card and an inspection object in a prober to a parallel state even if the contactor and the inspection object become not parallel to each other.

[Means for Solving the Problems]

The present invention is a probe card mounted in a prober via a holder, the probe card including: a contactor; a circuit board electrically connected to the contactor; a reinforcing member reinforcing the circuit board; and a parallelism adjustment mechanism which adjusts a degree of parallelism between the contactor and an inspection object disposed in the prober.

The parallelism adjustment mechanism may have a plurality of parallelism adjustment means for lifting up the probe card in the holder.

The circuit board and the reinforcing member may be overlaid on each other and may be coupled to each other via a plurality of fastening members.

The probe card may further include an intermediate member interposed between the contactor and the circuit board to make the contactor and the circuit board in elastic and electrical contact with each other.

The probe card may further include elastic members provided between the contactor and the circuit board and between the circuit board and the reinforcing member, respectively.

The probe card may further include a pressure adjustment mechanism which adjusts a contact pressure between the contactor and the circuit board.

The contactor may include: a ceramic substrate; and a plurality of probes provided on the ceramic substrate on a side of a contact surface which comes into contact with the inspection object.

### EFFECT OF THE INVENTION

According to the present invention, it is possible to conduct highly reliable inspection by adjusting a contactor of a probe card and an inspection object in a prober to a parallel state even if the contactor and the inspection object become not parallel to each other.

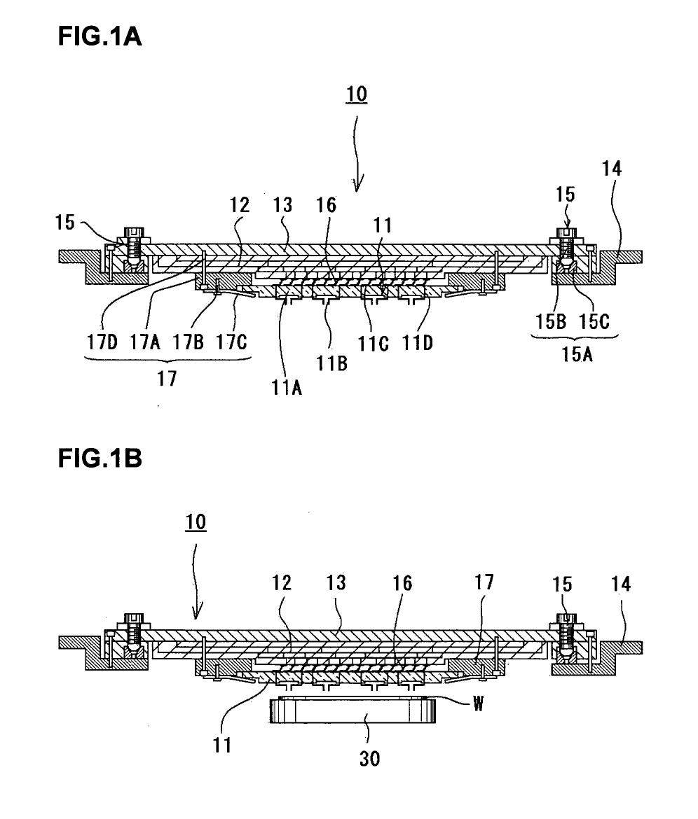

### BRIEF DESCRIPTION OF THE DRAWINGS

[FIG. 1]

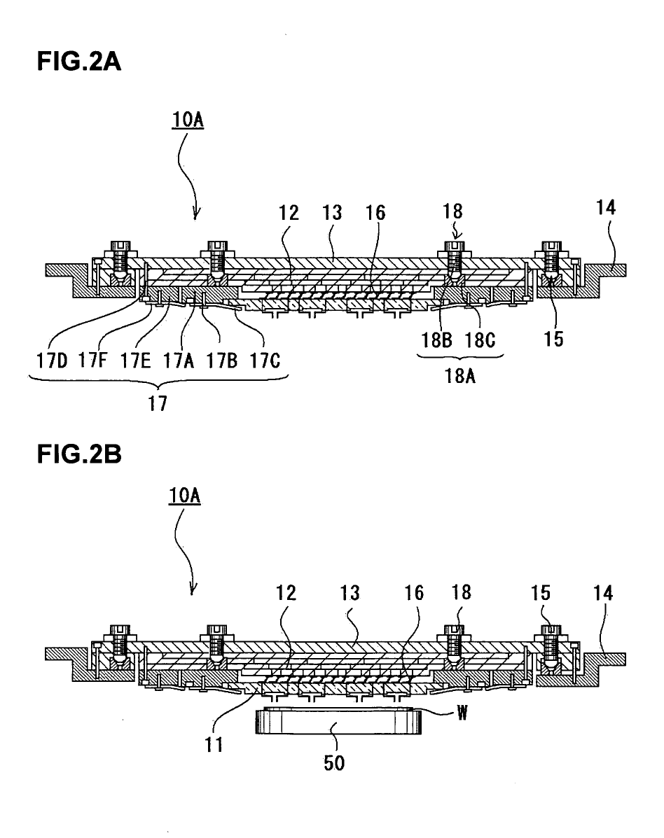

Cross-sectional views showing an embodiment of a probe card of the present invention, (a) being a cross-sectional view showing a state before adjustment and (b) being a cross-sectional view showing a state after a parallel state is adjusted.

[FIG. 2]

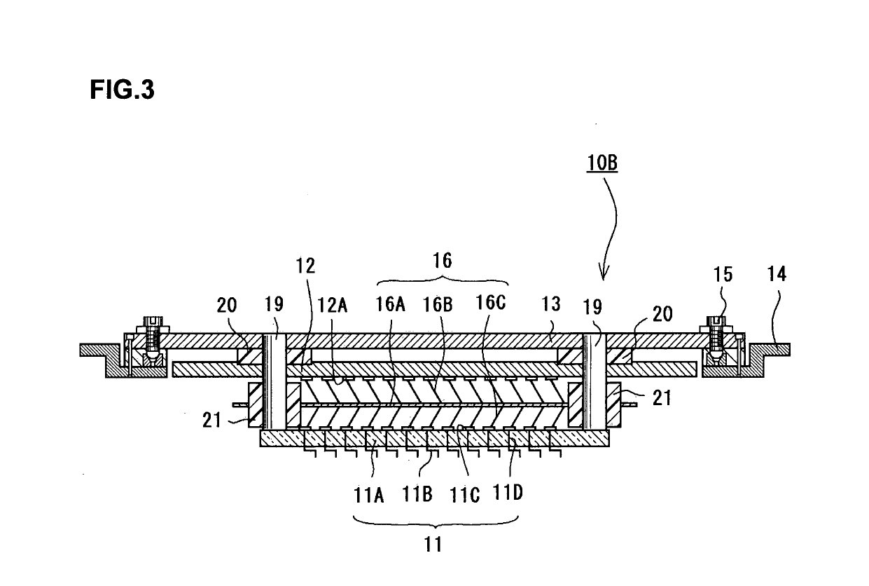

(a) and (b) are cross-sectional views, corresponding to FIGS. 1(a) and (b), showing another embodiment of the probe card of the present invention.

[FIG. 3]

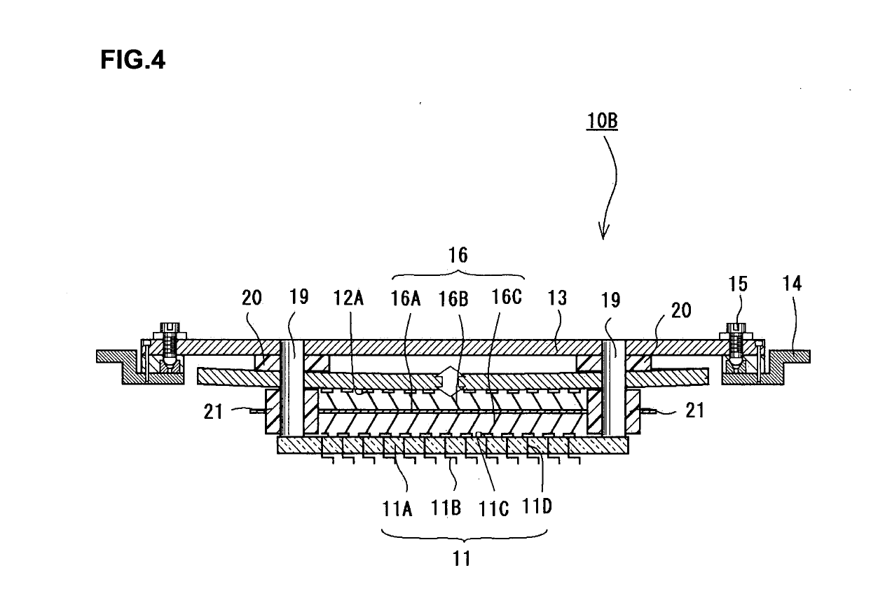

A cross-sectional view, corresponding to FIG. 1(a), showing still another embodiment of the probe card of the present invention.

[FIG. 4]

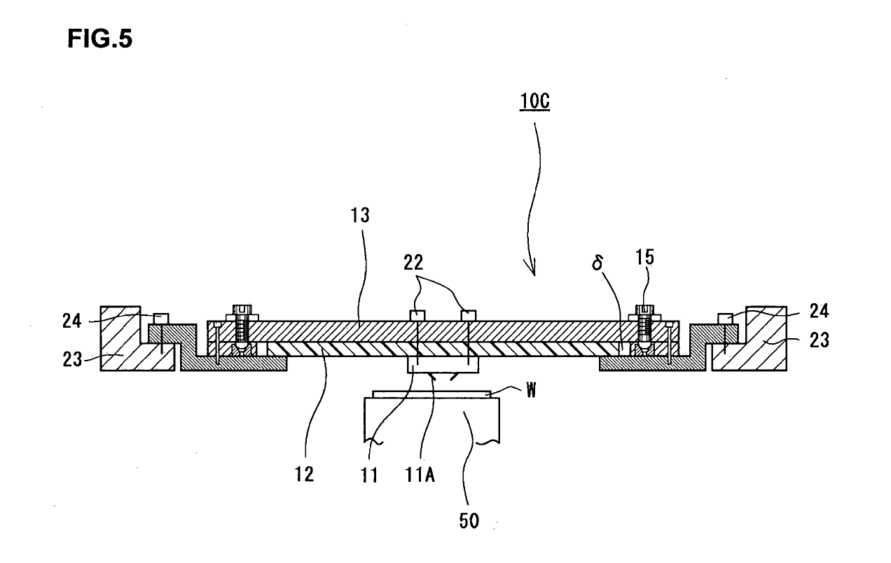

An explanatory view showing an influence of temperature in the probe card shown in FIG. 3.

[FIG. 5]

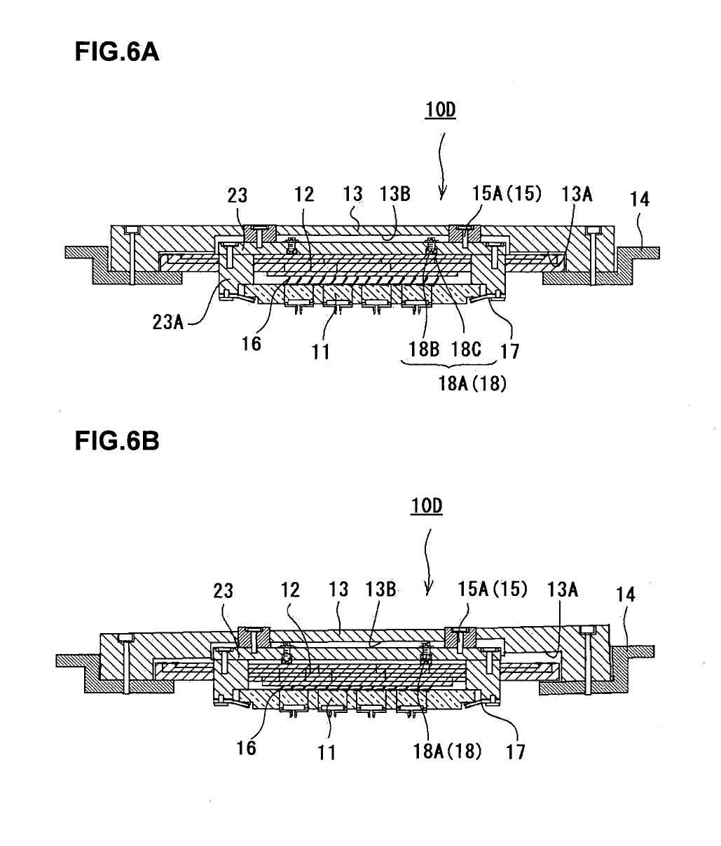

A cross-sectional view, corresponding to FIG. 1(a), showing yet another embodiment of the probe card of the present invention.

[FIG. 6]

(a) and (b) are cross-sectional views, corresponding to FIGS. 1(a) and (b), showing yet another embodiment of the probe card of the present invention.

[FIG. 7]

A front view showing an example of a prober, partly in cutaway.

[FIG. 8]

Views showing a conventional probe card, (a) being a cross-sectional view thereof and (b) being a cross-sectional view showing a state where a probe card and a wafer on a main chuck are adjusted to a parallel state.

### EXPLANATION OF CODES

10, 10A, 10B, 10C, 10D probe card
11 contactor
11A ceramic substrate
11B probe
12 printed wiring board (circuit board)
13 reinforcing member
14 card holder (holder)
15 parallelism adjustment mechanism
15A parallelism adjustment means
16 contact, interposer (intermediate member)
18 pressure adjustment mechanism
20, 21 elastic member

### BEST MODE FOR CARRYING OUT THE INVENTION

Hereinafter, the present invention will be described based on embodiments shown in FIG. 1 to FIG. 6. FIG. 1 are cross-sectional views showing an embodiment of a probe card of the present invention, (a) being a cross-sectional view showing a state before adjustment, and (b) being a cross-sectional view showing a state, after a parallel state is adjusted. FIGS. 2(a), (b) are cross-sectional views, corresponding to FIGS. 1(a), (b), showing another embodiment of the probe card of the present invention. FIG. 3 is a cross-sectional view, corresponding to FIG. 1(a), showing still another embodiment of the probe card of the present invention. FIG. 4 is an explanatory view showing an influence of temperature in the probe card shown in FIG. 3. FIG. 5 is a cross-sectional view, corresponding to FIG. 1(a), showing yet another embodiment of the probe card of the present invention. FIGS. 6(a), (b) are cross-sectional views, corresponding to FIGS. 1(a), (b), showing yet another embodiment of the probe card of the present invention.

### First Embodiment

As shown in, for example, FIGS. 1(a), (b), a probe card 10 of this embodiment includes: a contactor 11; a printed wiring board 12 electrically connected to the contactor 11; and a reinforcing member 13 reinforcing the printed wiring board 12, and the probe card 10 is mounted in a prober (not shown) via a holder (card holder) 14 when in use. As shown in FIGS. 1(a), (b), in an outer peripheral edge portion of the probe card 10, provided is a parallelism adjustment mechanism 15 which adjusts a degree of parallelism between the contactor 11 and a wafer W disposed on a mounting table (main chuck) in the prober. The parallelism adjustment mechanism 15 has a plurality of parallelism adjustment means 15A which lift up the probe card 10 from the card holder 14.

Further, the contactor 11 and the printed wiring board 12 are electrically connected to each other via a plurality of contacts 16. These contacts 16 are made of conductive metal such as, for example, tungsten to be elastically deformable. The contacts 16 have base ends connected respectively to a plurality of terminal electrodes formed on an upper surface of the contactor 11, and have upper ends electrically connected to a plurality of terminal electrodes formed on a lower surface of the printed wiring board 12.

As shown in FIGS. 1(a), (b), the contactor 11 has: a ceramic substrate 11A made of, for example, ceramic; a plurality of probes 11B provided on a lower surface of the ceramic substrate 11A in correspondence to a plurality of electrode pads (not shown) of the wafer W; terminal electrodes 11C formed on an upper surface of the ceramic substrate 11A in correspondence to the probes 11B; and connection wirings 11D formed in the ceramic substrate 11A to connect the terminal electrodes 11C and the probes 11B, and a plurality of chips formed on the wafer W can be simultaneously inspected. The contactor 11 can be formed by using microfabrication technology such as, for example, michromachining technology.

The contactor 11 is pressed and fixed to the printed wiring board 12 via a fastening means 17. As shown in FIGS. 1(a), (b), the fastening means 17 has: a fixing member 17A in a frame shape formed along an outer of the contactor 11 and having a recessed portion which is formed in an inner peripheral edge portion of its lower surface to receive an outer peripheral edge portion of the contactor 11; a plurality of leaf springs 17C attached to the lower surface of the fixing member 17A via screw members 17B and fixing the contactor 11 to the recessed portion of the fixing member 17A; and a plurality of screw members 17D fastening and fixing the fixing member 17A to the printed wiring board 12. By fixing the contactor 11 to the fixing member 17A by the leaf springs 17C, the plural contacts 16 of the contactor 11 and the terminal electrodes of the printed wiring board 12 are electrically connected to each other with a predetermined pressure.

The reinforcing member 13 is attached to an upper surface of the printed wiring board 12 as shown in FIGS. 1(a), (b) to prevent the printed wiring board 12 as much as possible from deforming due to a thermal influence. The reinforcing member 13 is made of, for example, a low-expansion alloy such as Invar low in coefficient of linear expansion and is thus formed so as to expand as little as possible even when heated at the inspection time. In a plane view, the reinforcing member 13 is composed of, for example: a ring formed along an outer peripheral edge portion of the printed wiring board 12; a disk portion formed on a center portion of the printed wiring board 12; and a plurality of radially disposed coupling portions coupling the ring portion and the disk portion at positions apart from one another in a circumferential direction or the like. Incidentally, as the printed wiring board 12, a conventionally known resin printed wiring board is usable.

Further, in an outer-side outer peripheral edge portion (concretely, the ring portion) of the reinforcing member 13, the plural parallelism adjustment means 15A are attached at a spacing distance in the circumferential direction or the like, and these parallelism adjustment means 15A constitute the parallelism adjustment mechanism 15. As shown in FIGS. 1(a), (b), each of the parallelism adjustment means 15A has: a bolt 15B screw-fitted with a female thread portion formed in the outer peripheral edge portion of the reinforcing member 13; and a receiving member 15C receiving a tip of the bolt 15B. By adjusting a screwing degree of the bolts 15B, it is possible to appropriately adjust a lifted degree of the printed wiring board 12 from the card holder 15. Incidentally, on a lower surface of a thick portion of the outer peripheral edge portion of the reinforcing member 13, a recessed portion in which the receiving members 15C are fitted is formed.

Therefore, when the probe card 10 is mounted in the prober via the card holder 14, if the contactor 11 and the wafer W on the main chuck 50 in the prober are not parallel to each other due to a machining error of each of the constituent members of the probe card 10, thermal deformation of the printed wiring board 12 and so on, and the like, the bolts 15B of the parallelism adjustment means 15A are operated to lift up the probe card 10 from the card holder 14 as shown in FIG. 1(b), so that the contactor 11 and the wafer W can be made parallel to each other.

As described above, the probe card 10 according to this embodiment includes the parallelism adjustment mechanism 15 which adjusts a degree of parallelism between the probe card 10 mounted in the prober via the card holder 14 and the wafer W disposed on the main chuck in the prober, and the parallelism adjustment mechanism 15 has the plural parallelism adjustment means 15A lifting up part of the peripheral edge portion of the probe card 10 from the card holder 14. Therefore, even if the contactor 13 of the probe card 10 and the wafer W on the main chuck 50 become not parallel to each other, by operating the parallelism adjustment means 15A, it is possible to adjust the degree of parallelism between the contactor 11 and the wafer W, so that the probes 11A of the contactor 11 can be brought into contact with the corresponding electrode pads of the wafer W with a uniform pressure, which enables highly reliable inspection.

### Second Embodiment

As shown in FIGS. 2(a), (b), a probe card 10A of this embodiment is structured in the same manner as the probe card 10 of the first embodiment except in that the probe card 10A has, in addition to the structure of the probe card 10 of the first embodiment, a pressure adjustment mechanism adjusting a pressure between a contactor and a printed wiring board. Therefore, in this embodiment, the same reference numerals and symbols are used to designate portions the same as or corresponding to those of the first embodiment, and characterizing portions of this embodiment will be mainly described.

As shown in FIGS. 2(a), (b), the probe card 10A of this embodiment includes: a parallelism adjustment mechanism 15; and a pressure adjustment mechanism 18 which is provided on an inner side of the parallelism adjustment mechanism 15 (concretely, for example, in a coupling portion) to adjust a contact pressure between a plurality of contacts 16 of a contactor 11 and a printed wiring board 12. Because the pressure adjustment mechanism 18 is provided, a fastening means 17 also has a different structure as that of the first embodiment.

As shown in FIGS. 2(a), (b), the fastening means 17 of this embodiment has: a first fixing member 17A in a frame shape formed along an outer of the contactor 11 and having a recessed portion which is formed in an inner peripheral edge portion of the first fixing member 17A to receive an outer peripheral edge portion of the contactor 11; a plurality of leaf springs 17C attached to a lower surface of the first fixing member 17A via screw members 17B to fix the contactor 11 to the recessed portion of the fixing member 17A; a second fixing member 17E disposed to surround the first fixing member 17A; a plurality of leaf springs 17F attached to a lower surface of the second fixing member 17E via screw members 17B to press and fix the first fixing member 17A to the printed wiring board 12 side; and a plurality of screw members 17D fastening and fixing the second fixing member 17E to the printed wiring board 12 side. The contactor 11 is pressed by the leaf springs 17C, so that a plurality of contacts 16 of the contactor 11 and terminal electrodes of the printed wiring board 12 are electrically connected with a predetermined pressure. Incidentally, on a lower surface of the printed wiring board 12, a recessed portion in which receiving members 18C are fitted is formed.

Further, a plurality of pressure adjustment means 18A are attached to an inner portion of a reinforcing member 13 at a spacing distance in a circumferential direction or the like, and these pressure adjustment means 18A constitute the pressure adjustment mechanism 18. As shown in FIGS. 2(a), (b), each of the pressure adjustment means 18A has: a bolt 18B screw-fitted with a female thread portion formed in the inner portion (for example, a coupling portion) of the reinforcing member 13; and the receiving member 18C receiving a tip of the bolt 18B. The receiving members 18C are fixed on the first fixing member 17A of the fastening means 17. By adjusting a screwing degree of the bolts 18B, it is possible to appropriately adjust a contact pressure between the plural contacts 16 of the contactor 11 and the terminal electrodes of the printed wiring board 12.

Therefore, when the probe card 10A is mounted in the prober via a card holder 14, if the contactor 11 and a wafer W on a main chuck in a prober are not parallel to each other due to a machining error of the probe card 10A, thermal deformation of the printed wiring board 12 and so on, and the like, the bolts 15B of the parallelism adjustment means 15A are operated to lift up the probe card 10A from the card holder 14 as shown in FIG. 2(b), so that the contactor 11 and the wafer W can be made parallel to each other. Furthermore, in a case where there is a possibility that contact failure occurs due to unevenness in contact pressure between the plural contacts 16 of the contactor 11 and the terminal electrodes of the printed wiring board 12, it is possible to stabilize the contact pressure of each of the contacts 16, by adjusting the pressure adjustment mechanism 18.

As described above, in this embodiment, the same operation and effect as those of the first embodiment can also be obtained, and in addition, the pressure adjustment mechanism 18 can stabilize electrical contact between the plural contacts 16 of the contactor 11 and the printed wiring board 12, which can further enhance reliability of the inspection.

### Third Embodiment

A probe card 10B of this embodiment is structured in the same manner as the first embodiment except in that this embodiment uses, as an interposer, contacts having a substrate instead of the contacts 16 of the above-described embodiments, thereby improving contact failure due to thermal deformation of the probe card 10B. Therefore, in this embodiment, the same reference numerals and symbols are used to designate portions the same as or corresponding to those of the first embodiment, and characterizing portions of this embodiment will be mainly described.

For example, as shown in FIG. 3, the probe card 10B includes: a contactor 11; a printed wiring board 12; a coupling member 19 coupling and integrating the contactor 11 and the printed wiring board 12; and a reinforcing member 13 reinforcing the printed wiring board 12 integrated by the coupling member 19. Further, between the contactor 11 and the printed wiring board 12, an interposer 16 making the contactor 11 and the printed wiring board 12 in elastic and electrical contact with each other is provided as an intermediate member, and the interposer 16 absorbs thermal deformation of the printed wiring board 12.

As shown in FIG. 3, the aforesaid interposer 16 has: a substrate 16A made of, for example, ceramic; a plurality of elastically deformable contacts 16B provided on an upper surface of the substrate 16A in correspondence to terminal electrodes 12A of the printed wiring board 12; a plurality of elastically deformable contacts 16C provided, on a lower surface of the substrate 16A in correspondence to terminal electrodes 11C of a ceramic substrate 11A; and via hole conductors (not shown) electrically connecting the contacts 16B, 16C on the upper and lower surfaces, and the interposer 16 is fixed to the coupling member 19 via a later-described elastic member.

The plural contacts 16B on the upper surface of the substrate 16A extend diagonally upward from the via hole conductors respectively, and come into electrical contact with the terminal electrodes 12A of the printed wiring board 12 via terminals 16E at, tips thereof. Further, the plural contacts 16C on the lower surface of the substrate 16A extend diagonally downward from the via hole conductors respectively, and come into electrical contact with the terminal electrodes 11C on an upper surface of the ceramic substrate 11A via terminals 16E at tips thereof. The contacts 16B, 16C are made of elastic metal, for example, tungsten or the like to be elastically deformable, and these contacts 16B, 16C have functions of not only electrically connecting the contactor 11 and the printed wiring board 12 but also absorbing thermal deformation of the printed wiring board 12.

Further, the upper and lower contacts 16B, 16C are structured to surely come into contact with the corresponding terminal electrodes 12A, 11C respectively in a state where the probe card 10B is thermally stabilized (a state at the inspection time). In other words, each of the terminal electrodes 12A of the printed wiring board 12 and the terminal electrodes 11C of the contactor 11 has a size large enough to surely come into contact with the contacts 16B, 16C of the interposer 16 even if the printed wiring board 12 is thermally deformed to the maximum degree.

Further, elastic members 20, 21 made of rubber or the like are fitted on upper and lower sides of the reinforcing member 13. These elastic members 20, 21 are interposed between the contactor 11 and the printed wiring board 12 and between the printed wiring board 12 and the reinforcing member 13, respectively. These elastic members 20, 21 in a state of being attached to the coupling member 19 absorb the thermal deformation of the printed wiring board 12 to stabilize the contact positions of the probes 11B.

Therefore, at the time of high-temperature inspection of a wafer (not shown), in a case where the contactor 11 of the probe card 10B and the wafer on a main chuck (not shown) become not parallel to each other, the parallelism adjustment mechanism 15 is operated prior to the inspection to make the contactor 11 and the wafer parallel to each other. Next, the main chuck is pre-heated for thermal stabilization. For the pre-heating, after or while the main chuck is heated up to a predetermined temperature by a temperature adjustment mechanism provided in the main chuck, the main chuck is moved closer to the probe card 10B, so that the probe card 10B is pre-heated by the main chuck. After the temperature of the probe card 10B is increased by the pre-heating, the printed wiring board 12 which is larger in coefficient of linear expansion than the other members of the probe card 10B thermally deforms to expand to a larger extent than the other members. At this time, since the periphery of the printed wiring board 12 is restricted by the coupling member 19, a thermal stress of the printed wiring board 12 can escape nowhere, so that the printed wiring board 12 gradually warps downward to bend as shown in FIG. 4 as it expands. On the other hand, since the contactor 11 and the reinforcing member 13 are far lower in coefficient of linear expansion than the printed wiring board 12, the contactor 11 and the reinforcing member 13 thermally deform only a little to maintain their flatness. Alternatively, providing the pressure adjustment mechanism 18 of the second embodiment instead of the coupling member 19 makes it possible to appropriately adjust the contact pressure with which the contacts 16B, 16C of the interposer 6 come into contact with the contactor 11 and the printed wiring board 12, which ensures stable electrical conduction.

As described above, in this embodiment, even if only the printed wiring board 12 in the probe card 10B bends downward, the upper contacts 16B of the interposer 16 absorb the bending of the printed wiring board 12 and the elastic members 20, 21 absorb the thermal deformation of the printed wiring board 12 in an area surrounding the coupling member 19, so that the thermal stress given from the printed wiring board 12 to the contactor 11 side is made ineffective, thereby maintaining flatness of the contactor 11. Further, even if the printed wiring board 12 thermally deforms to press the upper contacts 16B of the interposer 16 downward, the contacts 16B are positioned in the terminal electrodes 12A of the printed wiring board 12, so that the function of the interposer 16 is not impaired and electrical contact between the contactor 11 and the printed wiring board 12 can be maintained.

As described above, according to this embodiment, the probe card 10B includes: the contactor 11; the printed wiring board 12; the interposer 16 provided between the contactor 11 and the printed wiring board 12 to make the contactor 11 and the printed wiring board 12 in elastic and electrical contact with each other; the coupling member 19 integrating these; and the reinforcing member 13 reinforcing the printed wiring board 12 integrated via the coupling member 19. Therefore, even if the printed wiring board 12 bends downward due to the thermal deformation to give a stress to the contactor 11 side, elasticity of the interposer 16 makes this stress ineffective, so that positional displacement of the probes 11B of the contactor 11 from electrode pads of an inspection object can be prevented. Moreover, also owing to the operation of the parallelism adjustment mechanism 15, the plural probes 11B of the contactor 11 and the printed wiring board 12 come into contact with each other surely and uniformly via the interposer 16 even if the printed wiring board 12 gradually thermally deforms in accordance with the temperature increase of the probe card 10B up to the inspection temperature after the pre-heating. Therefore, the pre-heating need not be continued until the printed wiring board 12 is thermally stabilized, which can make the pre-heating time far shorter than the time conventionally required, resulting in enhanced throughput and highly reliable inspection.

### Fourth Embodiment

As shown in FIG. 5, a probe card 10C of this embodiment is structured in the same manner as the first embodiment except in that a contactor 11 of this embodiment is directly connected to a printed wiring board 12. Therefore, in this embodiment, the same reference numerals and symbols are used to designate portions the same as or corresponding to those of the first embodiment, and characterizing portions of this embodiment will be mainly described.

The probe card 10C has the structure to eliminate the thermal influence at the time of the inspection as much as possible similarly to the third embodiment, and a parallelism adjustment mechanism 15 is capable of making the contactor 11 and a wafer W disposed on a main chuck 50 parallel to each other. This embodiment is characterized in that the printed wiring board 12 is made difficult to bend due to thermal expansion. Specifically, in this embodiment, the contactor 11, the printed wiring board 12, and a reinforcing member 13 are coupled and integrated at a center portion of the reinforcing member 13 by a plurality of fastening members 22 constituted of screws or the like, as shown in FIG. 5. The plural fastening members 22 are arranged symmetrically around the vicinity of an axis of the reinforcing member 13, and therefore, even if the printed wiring board 12 thermally expands due to heat released from the main chuck 50 at the time of high-temperature inspection, the expansion of a center portion of the printed wiring board 12 due to the thermal expansion is small and thus the thermal deformation of the printed wiring board 12 in an up and down direction is reduced, so that the displacement of the contactor 11 in the up and down direction can be reduced.

An outer peripheral edge portion of the reinforcing member 13 is formed to have a thickness substantially equal to the sum of a thickness of its inner side portion and a thickness of the printed wiring board 12, and a gap 6 is formed between an inner surface of its outer peripheral edge portion and an outer peripheral surface of the printed wiring board 12, so that the thermal expansion of the printed wiring board 12 is absorbed in the gap. The probe card 10C is fixed to a card holder 14 via the reinforcing member 13. Note that in FIG. 5, 23 denotes a head plate, and the probe card 10C is fixed to the head plate 23 via the card holder 14 by fastening members 24.

Therefore, at the time of the high-temperature inspection, even if the temperature of the probe card 10C increases due to the heat released from the main chuck 50, the probe card 10C is fixed to the reinforcing member 13 by the plural fastening members 22 at its center portion. Therefore, there occurs little up-down direction displacement of the probe card 10C between the plural fastening members 22, and further, since an outer peripheral edge portion of the printed wiring board 12 is not fixed but is free, it is possible to reduce the up-down direction displacement of probes 11A. Further, the reinforcing member 13 and the card holder 14 are made of materials low in coefficient of thermal expansion, and therefore, even when the temperature of the reinforcing member 13 and the card holder 14 increases due to the influence of the heat released from the main chuck 15, the thermal expansion thereof can be reduced, which as a result can greatly reduce the up-down direction displacement of the probes 11A.

As described above, according to this embodiment, even if the contactor 11 and the wafer W on the main chuck 50 become not parallel to each other, the parallelism adjustment mechanism 15 is capable of adjusting the contactor 11 and the wafer on the main chuck 50 to a parallel state. Therefore, it is possible to surely bring the contactor 11 and the wafer W into electrical contact with each other, and moreover, the contactor 11, the printed wiring board 12, and the reinforcing member 13 are coupled together at the vicinity of their axes via the plural fastening members 22, and the outer peripheral edge portion of the printed wiring board 12 is not fixed but is free, so that it is possible to greatly reduce the up-down direction thermal deformation of the contactor 11, resulting in the reduction in the up-down displacement of the probes 11A, at the time of the high-temperature inspection, and it is also possible to prevent damage of electrode pads and base layers thereof, which can ensure high-temperature inspection without any trouble.

### Fifth Embodiment

As shown in FIGS. 6(a), (b), a probe card 10D of this embodiment includes: a parallelism adjustment mechanism 15 provided in an inner portion of a reinforcing member 13; and a pressure adjustment mechanism 18 provided on a little inner side of the parallelism adjustment mechanism 15 (concretely, for example, in radially formed coupling portions of the reinforcing member 13). Further, in this embodiment, a second reinforcing member 23 reinforcing a printed wiring board 12 is provided on an inner side of the reinforcing member 13, and the pressure adjustment mechanism 18 is attached to the second reinforcing member 23.

Specifically, as shown in FIGS. 6(a), (b), the reinforcing member 13 is attachable and detachable to/from a card holder 14 via fastening members such as screws disposed in an outer peripheral edge portion thereof. In a diameter-direction inner side of the reinforcing member 13, recessed portions 13A, 13B which become deeper by two stages are concentrically formed in sequence, and the second reinforcing member 23 of the printed wiring board 12 and a portion protruding from the printed wiring board 12 are fitted to the recessed portions 13A, 13B respectively.

As shown in FIGS. 6(a), (b), for example, the second reinforcing member 23 has, in a plane view: a ring formed along an outer peripheral edge portion of the printed wiring board 12; a disk portion formed on a center portion of the printed wiring board 12; and a plurality of coupling members coupling the ring portion and the disk portion at positions apart from one another in a circumferential direction or the like and radially formed, and the second reinforcing member 23 is formed substantially in a similar shape to the reinforcing member 13. The second reinforcing member 23 is disposed on the printed wiring board 12 so that the coupling portions thereof do not overlap with the coupling portions of the reinforcing member 13. A plurality of fixing members 17A of a fastening means 17 penetrating through the printed wiring board 12 and being apart from one another in a circumferential direction or the like are coupled to the ring portion of the second reinforcing member 23 via screw members, and screw members 17B and leaf springs 17C attached to lower end surfaces of the fixing members 17A press and fix the contactor 13 to recessed portions of the fixing members 17A.

The parallelism adjustment mechanism 15 is composed of a plurality of parallelism adjustment means 15A which are arranged in the coupling portions at a spacing distance in the circumferential direction or the like in the recessed portion 13B of the reinforcing member 13. The parallelism adjustment means 15A have bolts respectively, and are screw-fitted with female screws which are formed in the second reinforcing member 23 in correspondence to the bolts. A degree of parallelism between the contactor 11 and a wafer on a main chuck (not shown) can be adjusted depending on a screwing degree between the bolts of the plural parallelism adjustment means 15A and the female screws of the second reinforcing members 23.

Further, as shown in FIGS. 6(a), (b), a plurality of pressure adjustment means 18A which are positioned on the inner side of the plural fixing members 17A and are arranged in the coupling portions at a spacing distance in the circumferential direction or the like are attached to the second reinforcing member 23, and these pressure adjustment means 18A constitute the pressure adjustment mechanism 18. As shown in FIGS. 6(a), (b), each of the pressure adjustment means 18A has: a bolt 18B screw-fitted with a female screw portion formed in the inner portion (for example, in the coupling portion) of the second reinforcing member 23; and a receiving member 18C receiving a tip of the bolt 18B. The receiving members 18C are fixed on the printed wiring board 12. By adjusting a screwing degree of the bolts 18B, it is possible to appropriately adjust a contact pressure between a plurality of contacts 16 of the contactor 11 and terminal electrodes of the printed wiring board 12. These pressure adjustment means 18A are exposed in the plural radially formed coupling portions of the reinforcing member 13 and are capable of adjusting the contact pressure.

Therefore, in a case where the contactor 11 and the wafer on the main chuck in a prober become not parallel to each other when the probe card 10D is mounted in the prober via a card holder 14, by operating the bolts of the parallelism adjustment means 15A to lift up the reinforcing member 13 from the second reinforcing member 23 as shown in FIG. 6(b), it is possible to make the contactor 11 and the wafer W parallel to each other. Further, in a case where there is a possibility that contact failure occurs due to variation in contact pressure between a plurality of contacts 16 of the contactor 11 and the terminal electrodes of the printed wiring board 12, by operating the pressure adjustment mechanism 18, it is possible to stabilize the contact pressure of each of the contacts 16. That is, by operating the parallelism adjustment mechanism 15 while the probe card 10D is fixed to the card holder 14, it is possible to make the contactor 11 of the probe card 10D and the wafer on the main chuck parallel to each other, and by operating the pressure adjustment mechanism 18, it is possible to adjust the contact pressure between the contactor 11 and the printed wiring board 12.

As described above, the same operation and effect as those of the second embodiment can also be obtained in this embodiment. In addition, in this embodiment, since the parallelism adjustment mechanism 15 is disposed not on the card holder 14 but in the diameter-direction inner portion of the reinforcing member 13, it is possible to easily change the probe card 10D only by attaching and detaching the probe card 10D to/from the card holder 14 via the fastening members. This embodiment has described the probe card 10D including the pressure adjustment mechanism 18 as an example, but the pressure adjustment mechanism 18 may be omitted.

It should be noted that the present invention is not limited to the above-described embodiments at all, and any probe card including a mechanism which adjusts a parallel state between a probe card and an inspection object disposed in a prober is embraced in the present invention. Further, the parallelism adjustment means constituting the parallelism adjustment mechanism are not limited to bolts, and means for lifting the probe card from the card holder are all embraced in the present invention. Further, the shape and material of the contacts are not limited to specific ones, providing that the contacts are elastically deformable and have conductivity.

### INDUSTRIAL APPLICABILITY

The present invention can be suitably utilized as a probe card mounted in an inspection device.

What is claimed is:

1. A probe card mounted in a prober via a holder, the probe card comprising:
a contactor;
a circuit board electrically connected to said contactor;
a reinforcing member reinforcing said circuit board; and
a parallelism adjustment mechanism which adjusts a degree of parallelism between said contactor and an inspection object disposed in the prober.

2. The probe card according to claim 1,
wherein said parallelism adjustment mechanism has a plurality of parallelism adjustment means for lifting up the probe card in the holder.

3. The probe card according to claim 1,
wherein said circuit board and said reinforcing member are overlaid on each other and are coupled to each other via a plurality of fastening members.

4. The probe card according to claim 1, further comprising
an intermediate member interposed between said contactor and said circuit board to make said contactor and said circuit board in elastic and electrical contact with each other.

5. The probe card according to claim 4, further comprising
elastic members provided between said contactor and said circuit board and between said circuit board and said reinforcing member, respectively.

6. The probe card according to claim 5, further comprising
a pressure adjustment mechanism which adjusts a contact pressure between said contactor and said circuit board.

7. The probe card according to claim 1,
wherein said contactor includes: a ceramic substrate; and a plurality of probes provided on the ceramic substrate on a side of a contact surface which comes into contact with the inspection object.
